(19) United States
(12) Patent Application Publication
(10) Pub. No.: US 2019/0094134 A1
(43) Pub. Date: Mar. 28, 2019

(54) Compact Optical Gas Sensor with Spatial and Spectral Referense

(71) Applicants: Vyacheslav Solovyov, Rocky Point, NY (US); Mikhail Tkachuk, South Setauket, NY (US)

(72) Inventors: Vyacheslav Solovyov, Rocky Point, NY (US); Mikhail Tkachuk, South Setauket, NY (US)

(21) Appl. No.: 15/713,881

(22) Filed: Sep. 25, 2017

(51) Int. Cl. G01N 21/31; G01N 21/3504; H01L 33/06; H01L 33/08; G01J 5/08

(52) U.S. Cl. CPC G01N 21/314; G01N 21/3504; G01J 5/08; H01L 33/08; H01L 33/06

(57) ABSTRACT

Provided is a method for sensing gases using a compact optical gas sensor, a method for manufacturing same and a method for performing measurement of gas concentration using the optical absorption signal. The sensor design features a two-mirror geometry with long optical path. The sensor utilizes both spectral and optical reference channels. The reference channels ensure long-term stability of the sensor, which makes the design especially suitable for demanding environments requiring high reliability over extended period of time. The sensor operation is based on absorption of infrared light by a gas volume. In order to accurately determine the gas concentration, the absorption of the light that passed through the gas volume is compared with the absorption of the light of a different wavelength and absorption of light that traveled a short light path. A dual-color LED is used as a two-wavelength compact radiation source. The LED changes the emission wavelength as the excitation current is changing direction. The design is applicable to sensors for wearable gas alert devices, stationary leak detection, air quality monitoring, and any other field of applications that requires a specific gases' concentration detection.

### BACKGROUND OF THE INVENTION

The present invention relates to non-dispersive infrared (NDIR) spectroscopy of various gases. Gas sensing is often realized by an electrochemical method [“Solid State Gas Sensing” edited by Elisabetta Comini, Guido Faglia, Giorgio Sberveglieri, Springer Verlag Berlin Heidelberg, 2009], however this method is poorly suited for chemically passive gases such as methane or ethane. Combustible gases can be sensed by a hot filament or a heated catalyst device which measures the rate of catalytic oxidation of the gas in air. An example of such a device is a catalytic Pellistor [Krebs, P. and A. Grisel, A LOW-POWER INTEGRATED CATALYTIC GAS SENSOR. Sensors and Actuators B-Chemical, 1993. 13(1-3): p. 155-158.], which is typically designed to detect a combustible gas. Generated heat changes the resistance of the detecting element of the sensor proportional to the gas concentration. These devices require significant amount of power to operate, and cannot be practically designed as portable devices. NDIR utilizes strong optical absorption lines of common gases in 1-5 micrometer (μm) range of wavelengths for identification of the target gas species. Very little power is consumed in the measurement. [“Differential absorption spectroscopy”, U. Platt, J. Stutz, Springer Verlag Berlin Heidelberg, 2008]. One design of a spectrometer incorporates a tunable laser and a multi-pass optical cell. This design has been shown to deliver very high sensitivity, <1 ppm for common gases, and fast response. The approach would not obviously work for a household or a landline sensor, because of the cost of the infrared laser which may alone be as high as $500 and over. Another approach is to incorporate a broadband source of radiation, such as an incandescent bulb, and use a set of filters in order to differentiate absorption at different wavelengths. An incandescent bulb consumes several Watts of electric power, which makes this approach practical only for wired installations. An infrared light-emitting diode (LED) can replace the laser with an acceptable loss in sensitivity, however, the major problem with using an LED as the light source is absence of tunability of the LED radiation. A single spectral line coming of an LED cannot provide the “zero” reference outside the absorption range, which makes the sensor susceptible to temperature/time drifts and false alarms.

### SUMMARY OF THE INVENTION

The present invention relates to a design of a compact NDIR gas sensor. The design enables sensitivity to gases that have infrared light absorption peaks in 1-5 micron wavelength range. In this wavelength range, the detector can operate at room temperature and does not need to be actively cooled, which enables a compact and low-power sensor. The sensor operation is based on absorption of the infrared radiation by the gas volume. However, due to unavoidable ambient temperature variations, the electrical signal produced by the absorbed light can substantially change. This is especially relevant for the sensors based on photodetection properties of the narrow-band semiconductors, such as binary alloys In—As, In—Sb, Ga—Sb and ternary alloys Ga—In—Sb, which are sensitive to mid-IR (mid-infrared) radiation. This is because the band gap (the energy gap between valence band and conduction band) in these materials is less than 1 eV, which explains strong temperature dependence of both LED light emission intensity and the detector efficiency. It is well known that even several degrees Celsius change of the ambient temperature can dramatically compromise the response of a mid-IR detector. Since temperature stabilization is impractical for a low-power devices, the absorption signal received from the detector needs to be normalized by a reference signal which does not contain the gas target signature.

Thus, the present invention further relates to a method for compensation of temperature drift of a mid-IR detector by use of spatial and spectral reference channels, as described below. Here by channels, we understand distinct sets of electrical signals generated by the same or different detection means, which carry the information about the intensity of the IR radiation of certain wavelength coming from certain optical path.

The present invention further relates to a use of a dual-color LED, which is a semiconductor device that can emit two distinct wavelengths of light depending on the direction of the excitation current. A dual-line bidirectional LED is described in the U.S. Pat. No. 9,590,140 based on the following US application: 20160005921, “Bi-directional dual-color light emitting device and systems for use thereof”, and in the following publication: S. Jung, S. Suchalkin, G. Kipshidze, D. Westerfeld, E. Golden, D. Snyder and G. Belenky, Applied Physics Letters 96 (19) (2010).

In addition to the use of a dual-color LED for providing a spectral reference channel, a sensor with dual optical path is provided, with one optical path being substantially shorter than the other. The amount of the light absorbed by a target detection gas depends exponentially on the length of the optical path. Therefore, by providing a second optical path being 3-10 times shorter helps distinguishing the gas absorption and detector sensitivity variations by comparing the channels with long optical path (high absorption in presence of target gas) and with short optical path (less absorption in presence of target gas). The shorter optical path is called for the purpose of the present invention a spatial reference channel. However, it is the spectral channel which provides the main reference signal.

Additionally, incorporation of a channel with a short optical path allows extending dynamic range of the sensor. When concentration of the target gas is so high that the long-path channel is saturated (all the light is absorbed), the short-path channel can still be used to measure the target gas concentration.

Additional features, advantages, and embodiments of the present invention may be set forth from consideration of the following detailed description, drawings, and claims. Moreover, it is to be understood that both the foregoing summary of the present disclosure and the following detailed description are exemplary and intended to provide further explanation without limiting the scope of the present disclosure claimed.

### BRIEF DESCRIPTION OF THE DRAWINGS

FIG. 1 is an illustrative view of the NDIR optical gas sensing gauge with both spatial and spectral reference channels.

FIG. 2a is a cross-sectional view of the sensor showing location of the mirrors and the optical path for both signal and short path (reference) channels.

FIG. 2b is a cross-sectional view of the sensor showing detail of optcal components that comprise the short optical path.

FIG. 3 is the absorption spectra of methane gas and water vapor. Superimposed are spectral emission curves of the dual-color LED on the signal (λ1) and reference (λ2) wave-lengths.

FIG. 4a shows photoemission spectra pattern of a dual color LED manufactured by bulk p-n junction technology.

FIG. 4b shows photoemission spectra pattern of a dual color LED manufactured by quantum well technology.

FIG. 5 is an illustration showing timing diagram of the sensor operation.

### DETAILED DESCRIPTION OF THE INVENTION

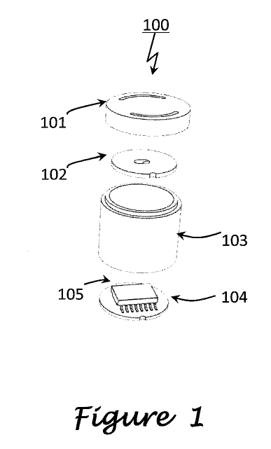

The generalized components arrangement of the optical gas sensor of the present invention 100 is shown in FIG. 1. Sensor 100 comprises a spherical mirror 101, and a flat mirror 102. Both mirrors are mounted in a housing 103. Light processing circuit 105 is mounted on a printed circuit board 104, and the board is mounted inside the sensor housing 103.

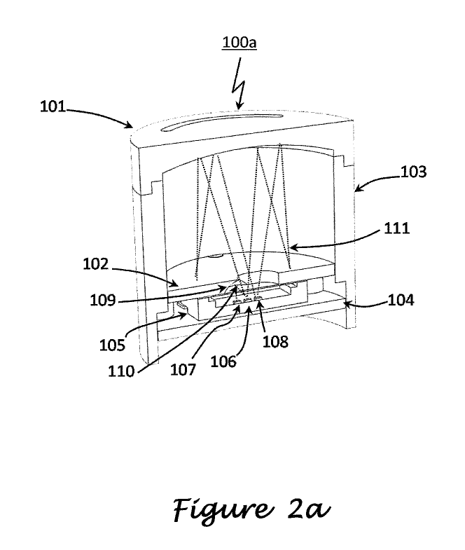

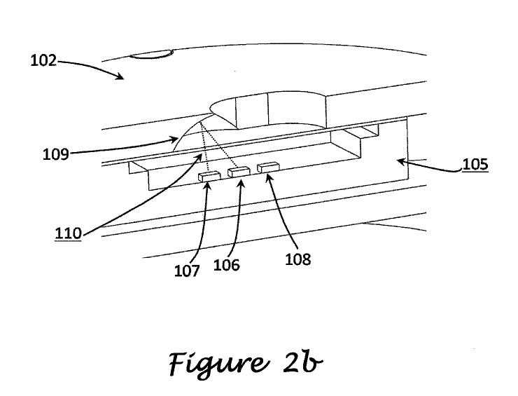

FIG. 2a is a cross-section of an optical gas sensor device of the present invention. Infrared light is emitted by a light-emitting diode 106. Light is first reflected from a spherical mirror 101, reflected from a flat mirror 102, back to the spherical mirror 101 and is finally focused at detector 108. Thus the light path is close to four times the height of the detector housing 103. For example, the total said light path can be between three times and four times the height of the detector housing. For example, the detector housing height can be between 10 and 40 millimeters (mm).

FIG. 2b shows detail of the short optical path. Part of the light is collected by an elliptical mirror 109. The mirror focuses a portion of light emitted by LED 106 onto reference signal detector 107. Optical path of light in the reference channel, 110, is approximately ten times shorter than the optical path length of the principal signal, 111. Therefore, the target gas signature in the reference signal channel is much smaller than the one in the main channel. The signal generated by the reference signal detector 107 can, therefore, serve as a spatial reference channel.

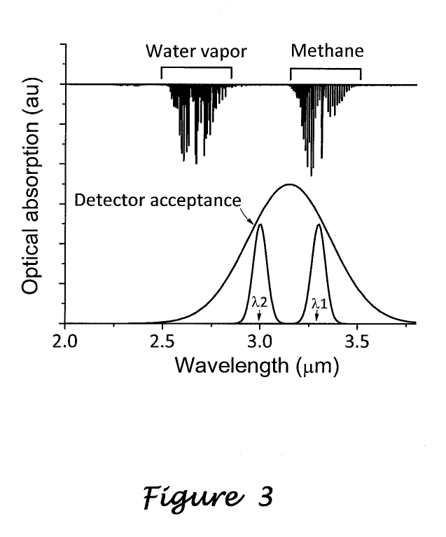

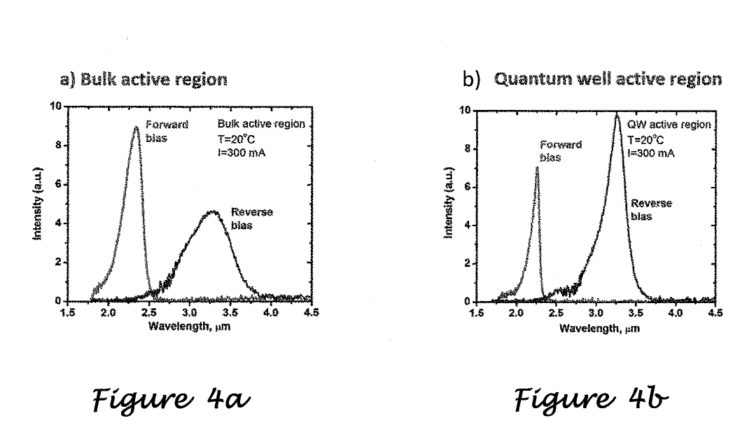

LED 108 is of dual color type, such as described in the U.S. Pat. No. 9,590,140 based on the following application: 20160005921, “Bi-directional dual-color light emitting device and systems for use thereof”. FIG. 3 shows how the dual-color emission enables methane sensing. Methane has several strong absorption lines in mid-IR wavelength range, spanning from 3.2 to 3.5 microns, with the strongest emission line at 3.3 microns. Water vapor, naturally present in the ambient atmosphere, has strong absorption in the range from 2.5 to 2.8 microns. In one of the embodiments of the present invention, the signal line, the wavelength λ1, is located at 3.3 microns, where absorption of methane gas is the strongest. The reference line used as a source of the signal for spectral reference channel, the wavelength λ2, is located outside the methane absorption range, as indicated in FIG. 3, for example at 3.0 microns. The reference emission line is positioned so that the reference signal is insensitive to both methane and water vapor presence. In certain situations, another strongly absorbing gas can interfere with the reference reading. In this case the reference line can be located on the right side of the absorption spectrum feature, for example at 4.5 microns. FIGS. 4a and 4b show example of emission spectra of methane-specific LEDs manufactured using a bulk p-n junction and a quantum well technology, respectively. Both curves show that under the reverse bias the LED emits radiation centered around the methane absorption line, 3.2 μm, when the bias is reversed the radiation wavelength shifts to 2.2 μm wavelength.

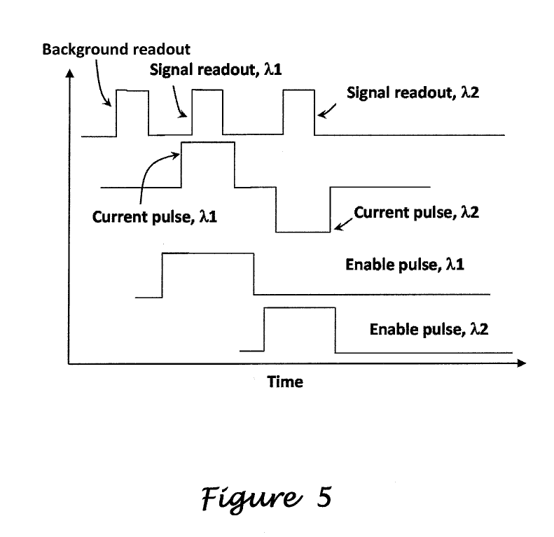

In order to reduce the power consumption by the device, the measurement is performed in a pulsed mode explained in detail in FIG. 5. A controlling microprocessor unit generates the “enable” signal which turns on an amplifier circuitry, which otherwise is in the “sleep” mode. After certain period of time, the control unit reads the background signal. After the background signal is registered, the infrared light is generated by supplying current of a first direction to the LED and the optical signal absorption is measured at the wavelength λ1. During the light pulse, both spatial reference and signal channels are read by the control unit. The same sequence is repeated using the infrared light generated by supplying current of a second direction to the LED, thus for both long and short paths the optical absorption is measured at the wavelength λ2. A digital processor compares the four reading: the short and long path absorption at the wavelength λ1 and the short and long path absorption at the wavelength λ2. This reading allows detecting presence of interfering gas at the reference wavelength λ2. The target gas concentration is determined by fitting the four reading to a calibration function of the sensor. After the measurement is completed, the said amplifying circuitry returns to the “sleep” mode. At the end of the measurement cycle, the control unit analyzes the received signal and calculates the gas concentration.

It is understood that other methods or materials can be used to construct a similar sensor.

### EXAMPLES

In the following detailed description, reference is made to the accompanying drawings, which form a part hereof. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present invention, as generally described herein, and illustrated in the figures, can be arranged, substituted, combined, and designed in a wide variety of different configurations, all of which are explicitly contemplated and made part of this disclosure.

### Example 1

The sensor body was machined from Acrylonitrile Butadiene Styrene (ABS) plastic. The mirror surfaces were coated with 1 micron gold layer. LED, reference and signal detectors were mounted on a single chip carrier 105, as shown in FIG. 1. The LED and detectors were spectrally matched Ga—Sb Type I quantum well structures or bulk strcutures that were optimized for 3.3 micron wavelength. Details of the quantum well structure fabrication were previously described in the following publication: [Jung, S., S. Suchalkin, G. Kipshidze, D. Westerfeld, D. Snyder, M. Johnson, and G. Belenky, “GaSb-Based Type I Quantum-Well Light-Emitting Diode Addressable Array Operated at Wavelengths Up to 3.66 um.” IEEE Photonics Technology Letters, 2009. 21(15): p. 1087-1089]. FIGS. 4a and 4b shows the emission spectra of the LEDs, whereas the reverse bias of the LED corresponds to emission centered around 3.2 μm, which is the maximum absorption for methane and the forward bias corresponds to a shorter wavelength, approximately 2.2 μm, which serves as the spectral reference line. The LED was excited by 300 mA current with 20 micro-second pulses. The main signal and reference channel signal were amplified by a known in art double-stage amplifier. The amplified signal was converted to a digital form by an analog-digital converter comprised by the control unit. The device is housed in a plastic body 103, 18 mm in diameter and 22 mm tall. The body is comprised of a spherical mirror 101 and a flat mirror 102. All the body parts were machined from ABS plastic; after the machining, the reflecting surfaces 101 and 102 were polished and plated with Gold by an electrochemical method. The mirrors were then glued to the sensor body by epoxy glue. The printed circuit board, 104, accommodated a digital processor (PIC brand, Microchip Technology) and signal conditioning circuits. The sensor communicated with the gas controller via serial (RS232) communication protocol. The sensor operated according to the timing diagram shown in FIG. 5. The sensor was activated for 60 micro-seconds (duration of the “enable” pulse) every 50 milliseconds. The length of the current pulse was approximately 30 micro-seconds, during the pulse the light intensity was collected for approximately 15 micro-seconds. The readout sequence was comprised on the background readout, the light signal measurement at the reference wavelength λ1 (3.0 micrometers) and methane absorption wavelength (3.3 micrometers). The sensor was powered by a 3.2 Volts Li-ion battery, consuming, on average, 200 microwatts of electrical power. The sensor detected 2% of methane in air with better than 0.1% error.

1. A compact low-power Near-Infrared Absorption sensor for detecting gaseous species in the air, comprising:
a dual-color infrared light emitting diode operating under first and second directions of the current conduction depending on the electric bias applied to its terminals at consequent instances of time and producing infrared radiation of a first wavelength when biased to conduct electric current of a first direction, and producing infrared radiation of a second wavelength when biased to conduct electric current of a second direction;
at least one spherical mirror;
at least one flat mirror;
at least one broadband infrared detector with a bandwidth that includes at least the first and the second said wavelengths;
the said sensor further designed in such a way that at least one of the said broadband detectors is measuring the intensity of the light produced by the said light emitting diode both at the first and the second wavelengths, after the said produced light travels a first optical path inside the said sensor, the said first optical path created by the arrangement of the said mirrors and exceeding in length the physical dimension of the said sensor at least by a factor of three.

2. A sensor of claim 1 further comprising a second broadband infrared detector with a bandwidth that includes at least the first and the second said wavelengths, measuring the intensity of the light generated by the said light emitting diode both at the first and the second wavelengths, arranged to measure the intensity of the said light after it travels a second optical path that is shorter than the physical dimension of the said sensor, and also is shorter than the length of the said extended optical path by at least a factor of ten.

3. A sensor of the claim 1, where the emission wavelengths of the dual-color light emitting diode are selected in such a way that the light of the said first wavelength is absorbed distinctly more effectively than the light of the said second wavelength by potentially dangerous concentration of a target gas selected from the group of combustible gas, such as methane, and hazardous gas, such as ammonia.

4. A sensor of the claim 2, where the emission wavelengths of the dual-color light emitting diode are selected in such a way that the light of the said first wavelength is absorbed distinctly more effectively than the light of the said second wavelength by potentially dangerous concentration of a target gas selected from the group of combustible gas, such as methane, and hazardous gas, such as ammonia.

5. A sensor of claim 3 performing functions of:
exciting the dual-color light emitting diode by a pulsed current of alternating directions to produce the pulses of light of the first wavelength alternated with the pulses of light of the second wavelength;
detecting the produced pulses of light;
comparing the radiation intensity of the light traveled the first optical path and the second optical path;
detecting presence of interfering gas absorbing at the reference wavelength;
performing correction of the reference signal depending on concentration of interfering gas.

6. A sensor of claim 4 performing functions of:
exciting the dual-color light emitting diode by a pulsed current of alternating directions to produce the pulses of light of the first wavelength alternated with the pulses of light of the second wavelength;
detecting the produced pulses of light;
comparing the radiation intensity of the light traveled the first optical path and the second optical path;
comparing the radiation intensity of the light of the first and the second wavelength after the light traveled over first and second optical path;
detecting presence of interfering gas absorbing at the reference wavelength;
performing correction of the reference signal depending on concentration of interfering gas.

7. A sensor of claim 6, where the comparison of the light intensity traveled the first and the second optical paths is used to extend the operation range of the sensor to high gas concentrations.

8. A sensor of claim 4 performing functions of:
exciting the dual-color light emitting diode by a pulsed current of alternating directions to produce the pulses of light of the first wavelength alternated with the pulses of light of the second wavelength;
detecting the produced pulses of light;
comparing the radiation intensity of the light traveled the first optical path and the second optical path;
comparing the radiation intensity of the light of the first and the second wavelength after the light traveled over first and second optical path;
detecting presence of interfering gas absorbing at the reference wavelength;
performing correction of the reference signal depending of concentration of interfering gas,
where the sensor of claim 4 is used for simultaneous detection of two gases by comparing the radiation intensity of the light traveled the first optical path and the second optical path, and comparing the radiation intensity of the light of the first and the second wavelength, where the measured intensity of the light traveled the second optical path signal is used as the reference.

9. A method for manufacturing the low-power sensor as in one of the claims 1-2, comprising:
mounting the dual-color LED and the at least one broad-band infrared detector on a single chip carrier;
mounting the said chip carrier on a printed circuit board;
providing an optical system comprising the said mirrors, the optical system manufactured using plastic by either machining or injection molding;
performing the sensor assembly that aligns the optical system and the LED-detector single chip carrier by a set of mechanical keys.

10. A method for measuring concentration of a target gas using infrared-absorption spectroscopy, comprising the steps of:
exciting the dual-color light emitting diode by a pulsed current of alternating directions to produce the pulses of light of the first wavelength alternated with the pukes of light of the second wavelength;
performing detection of the produced pulses of light;
performing comparison of the radiation intensity of the light traveled the first (long) optical path and the second (short) optical path;
performing comparison of the radiation intensity of the light of the first and the second wavelength after the light traveled over first (long) and second (short) optical path.
detecting presence of interfering gas absorbing at the reference wavelength;
performing correction of the reference signal depending of concentration of interfering gas.

11. A method for measuring concentration of a target gas using infrared-absorption spectroscopy, comprising the steps of:
exciting the dual-color light emitting diode by a pulsed current of alternating directions to produce the pulses of light of the first wavelength alternated with the pulses of light of the second wavelength;
performing detection of the produced pulses of light;
performing comparison of the radiation intensity of the light travelled the first (long) optical path and the second (short) optical path;
performing comparison of the radiation intensity of the light of the first and the second wavelength after the light traveled over first (long) and second (short) optical path.
detecting presence of interfering gas absorbing at the reference wavelength;
performing correction of the reference signal depending of concentration of interfering gas,
performing simultaneous detection of two gases by comparing the radiation intensity of the light traveled the long optical path and the short optical path, and comparing the radiation intensity of the light of the first and the second wavelength, where the measured intensity of the light traveled the short optical path signal is used as the reference.
